(19) United States
(12) Patent Application Publication
(10) Pub. No.: US 2026/0006923 A1
(43) Pub. Date: Jan. 1, 2026

(54) PIXEL WITH VERTICAL TRANSFER GATE

(71) Applicant: OMNIVISION TECHNOLOGIES, INC., Santa Clara, CA (US)

(72) Inventors: Satoshi NAKAYAMA, Kanagawa (JP); Nagataka TANAKA, Kanagawa (JP)

(73) Assignee: OMNIVISION TECHNOLOGIES, INC., Santa Clara, CA (US)

(21) Appl. No.: 19/236,524

(22) Filed: Jun. 12, 2025

Related U.S. Application Data
(60) Provisional application No. 63/664,758, filed on Jun. 27, 2024.

(51) Int. Cl. H10F 39/00

(52) U.S. Cl. CPC H10F 39/80373; H10F 39/807; H10F 39/809

(57) ABSTRACT

The image sensor comprises a semiconductor layer and a vertical gate structure. The semiconductor layer has a first side and a second side opposite to the first side. The semiconductor layer includes a first photodiode and a second photodiode adjacent to the first photodiode. The vertical gate structure is disposed between the first photodiode and the second photodiode. The vertical gate structure includes a planar portion and a vertical gate portion. The planar portion is disposed proximate to the first side. The vertical gate portion is extended from the planar portion a depth into the semiconductor layer.

### CROSS REFERENCE TO RELATED APPLICATION

This application claims priority to the provisional Application No. 63/664,758, filed on Jun. 27, 2024, which is incorporated herein by reference in its entirety including the specification, claims, drawings, and abstract.

### TECHNICAL FIELD

This disclosure relates to an image sensor and more particularly but not exclusively relates to an image sensor having a pixel with vertical gate structure.

### BACKGROUND

Image sensors have become ubiquitous and are now widely used in digital cameras, cellular phones, security cameras, as well as medical, automobile, and other applications. As image sensors are integrated into a broader range of electronic devices it is desirable to enhance their functionality, performance metrics, and the like in as many ways as possible (e.g., resolution, power consumption, dynamic range, etc.) through both device architecture design as well as image acquisition processing.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge of each of the pixels may be measured as an output voltage of each photosensitive element that varies as a function of the incident image light. In other words, the amount of image charge generated is proportional to the intensity of the image light, which is utilized to produce a digital image (i.e., image data) representing the external scene.

As the pixel size in an image sensor kept on shrinking, isolation between active regions become critical for pixel design as leakage issue is more likely happened. For example, if isolation between adjacent photodiodes is weak, signal charge leakage toward neighbor photodiode will occur, in particular in a strong light situation. This phenomenon may be referred as blooming resulting undesired image artifact. Blooming is a type of optical crosstalk that occurs when, in response to light incident on a pixel, the quantity of photoelectrons accumulated in a pixel's photodiode exceeds the pixel's saturation level (full well capacity), such that excess photoelectrons are detected by one or more adjacent pixels.

### SUMMARY

In this specification, an image sensor is disclosed. The image sensor comprises a semiconductor layer, a floating diffusion, a transfer gate, and a vertical gate structure. The semiconductor layer has a first side and a second side opposite to the first side. The semiconductor layer includes a first photodiode and a second photodiode adjacent to the first photodiode. The floating diffusion is disposed in the semiconductor layer proximate to the first side. The transfer gate on the semiconductor layer, couples the first photodiode to the floating diffusion. The transfer gate comprises a vertical transfer gate extending a gate depth from the first side of the semiconductor layer into the semiconductor layer. The vertical gate structure is disposed on the semiconductor layer between the first photodiode and the second photodiode. The vertical gate structure includes a planar portion disposed proximate to the first side and a vertical gate portion extending from the planar portion a depth into the semiconductor layer. The gate depth is the same as the depth that the vertical gate portion of the vertical gate structure extends.

In this specification, the transfer gate and the vertical gate structure may be formed of same composition.

In this specification, the transfer gate and the vertical gate structure comprise polysilicon material.

In this specification, the image sensor may further comprises a second vertical gate structure. The second vertical gate structure is disposed separating the first photodiode from a transistor region containing at least one of row select transistor, reset transistor and the source follower transistor.

In this specification, the image sensor may further comprises a third vertical gate structure. The third vertical gate structure is disposed separating a transistor from a ground contact.

In this specification, the vertical gate structure and the second vertical gate structure may be interconnected surrounding the first photodiode.

In this specification, the vertical gate structure may be coupled to receive a ground reference or a negative bias voltage.

In this specification, the semiconductor layer may be a first wafer layer. The vertical gate structure and the first photodiode are disposed on the first wafer layer. At least one of row select transistor, reset transistor and the source follower transistor are disposed on a second wafer layer vertically stacked on the first wafer layer.

In this specification, the ground contact may be vertically aligned with the vertical gate structure.

In this specification, the image sensor may further comprises a backside deep trench isolation structure. The backside deep trench isolation structure is disposed on the second side of the semiconductor layer. And the backside deep trench isolation structure is vertically aligned with the vertical gate structure.

In this specification, a vertical gap may be located between the vertical gate structure and the backside deep trench isolation structure.

In this specification, the vertical gate structure may be separated from the semiconductor layer by a dielectric layer.

In this specification, an image sensor structure is disclosed. The image sensor Comprises a first wafer and a second wafer. The first wafer comprises a first semiconductor layer, a photodiode, a floating diffusion, a transfer gate, and a vertical gate structure. The first semiconductor layer has a first side and a second side opposite to the second side. The photodiode has a photodiode doped region disposed in the first semiconductor layer proximate to the first side of the first semiconductor layer. The floating diffusion is disposed in the first semiconductor layer proximate to the first side. The transfer gate on the semiconductor layer coupes the first photodiode to the floating diffusion. The transfer gate comprises a vertical transfer gate extending a gate depth from the first side of the semiconductor layer into the first semiconductor layer. The vertical gate structure is disposed on the first semiconductor layer between the photodiode and a photodiode doped region of an adjacent second photodiode. The vertical gate structure includes a planar portion disposed proximate to the first side and a vertical gate portion extending from the planar portion a depth into the first semiconductor layer. The second wafer is stacked on the first wafer. The second wafer comprises a second semiconductor layer and a doped region. The second semiconductor layer is disposed on the first semiconductor layer. The doped region has a impurity polarity same as that of the second semiconductor layer. The doped region is coupled to receive a ground voltage. The doped region is coupled to the vertical gate structure.

In this specification, the doped region may be vertically aligned with the vertical gate structure.

In this specification, the image sensor may further comprises a vertical contact structure coupled the doped region to the vertical gate structure.

In this specification, the second wafer further may comprises at least one of row select transistor, reset transistor and the source follower transistor disposed on a second semiconductor layer.

In this specification, the gate depth may be the same as the depth that the vertical gate portion of the vertical gate structure extends.

In this specification, the image sensor may further comprises a second vertical gate structure that is disposed between the floating diffusion and a photodiode doped region of an adjacent third photodiode.

### BRIEF DESCRIPTION OF DRAWINGS

Non-limiting and non-exhaustive examples of the invention are described with reference to the following figures, and like reference numerals refer to like parts throughout the various views unless otherwise specified, wherein:

FIGS. 1A and 1B show an example of blooming.

FIGS. 2A and 2B show another example of blooming.

FIGS. 3A and 3B show an example of pixels structure with a blooming path.

FIGS. 4A-4C show a pixel structure accordance to the first embodiment.

FIG. 5 shows the pixel structure accordance to the second embodiment.

FIGS. 6A and 6B show the pixel structure accordance to the third embodiment.

FIG. 7 shows the pixel structure accordance to the fourth embodiment.

FIGS. 8A and 8B show the pixel structure accordance to the fifth embodiment.

FIG. 9 illustrates a block diagram of an imaging system accordance to the present disclosure.

### DESCRIPTION OF EMBODIMENTS

The term “first”, “second” or the like used herein may modify various elements regardless of order and/or priority, but does not limit the elements. Such terms may be used to distinguish one element from another element. For example, “a first user device” and “a second user device” may indicate different user devices regardless of order, or formation sequence, or priority. For example, without departing the scope of the present disclosure, a first element may be referred to as a second element and vice versa. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It is appreciated that the term “photodiode doped region” may correspond to a region within the semiconductor substrate that has been doped, for example by ion implantation, to have an opposite charge carrier type (i.e., conductivity type) relative to the majority charge carrier type of the semiconductor substrate such that an outer perimeter of the doped region (e.g., herein referred to as a photodiode region) forms a PN junction or a PIN junction of a photodiode. For example, an N-doped region, formed in a P-type semiconductor substrate, forms a corresponding photodiode region. In some embodiments, a given pixel may further include a pinning region (e.g., a doped region disposed between a side of the semiconductor substrate and the photodiode doped region having a conductivity type opposite of the photodiode doped region conductivity type) to form a pinned photodiode. For example, the pinning region has a P-type conductivity and the photodiode doped region has an N-type conductivity.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

Further still, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The term “have”, “may have”, “include”, “may include” or “comprise” used herein indicates the existence of a corresponding feature (e.g., a number, a function, an operation, or an element) and does not exclude the existence of an additional feature.

The term “A or B”, “at least one of A and/or B”, or “one or more of A and/or B” may include all possible combinations of items listed together. For example, the term “A or B”, “at least one of A and B”, or “at least one of A or B” may indicate all the cases of (1) including at least one A, (2) including at least one B, and (3) including at least one A and at least one B.

It will be understood that when a certain element (e.g., a first element) is referred to as being “operatively or communicatively coupled with/to” or “connected to” another element (e.g., a second element), the certain element may be coupled to the other element directly or via another element (e.g., a third element). However, when a certain element (e.g., a first element) is referred to as being “directly coupled” or “directly connected” to another element (e.g., a second element), there may be no intervening element (e.g., a third element) between the element and the other element.

The term “configured (or set) to” may be interchangeably used with the term, for example, “suitable for”, “having the capacity to”, “designed to”, “adapted to”, “made to”, or “capable of”. The term “configured (or set) to” may not necessarily have the meaning of “specifically designed to”. In some cases, the term “device configured to” may indicate that the device “may perform” together with other devices or components. For example, the term “processor configured (or set) to perform A, B, and C” may represent a dedicated processor (e.g., an embedded processor) for performing a corresponding operation, or a generic-purpose processor (e.g., a CPU or an application processor) for executing at least one item of software or program stored in a memory device to perform a corresponding operation.

In the following description, numerous specific details are given to provide a thorough understanding of embodiments. The embodiments can be practiced without one or more of the specific details, or with other methods, components, materials, etc. In other instances, well-known structures, materials, or operations, such as, for example, processors, spectrometers, etc., are not shown or described in detail to avoid obscuring aspects of the embodiments.

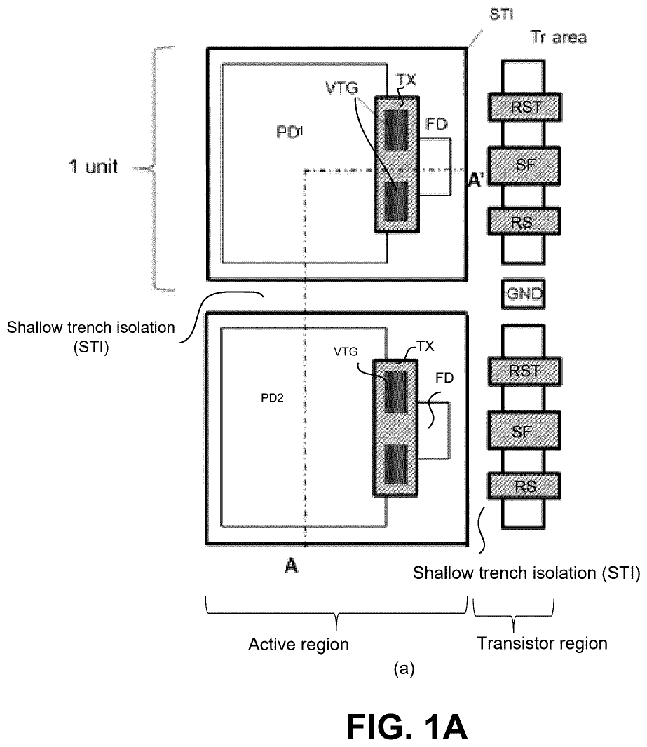

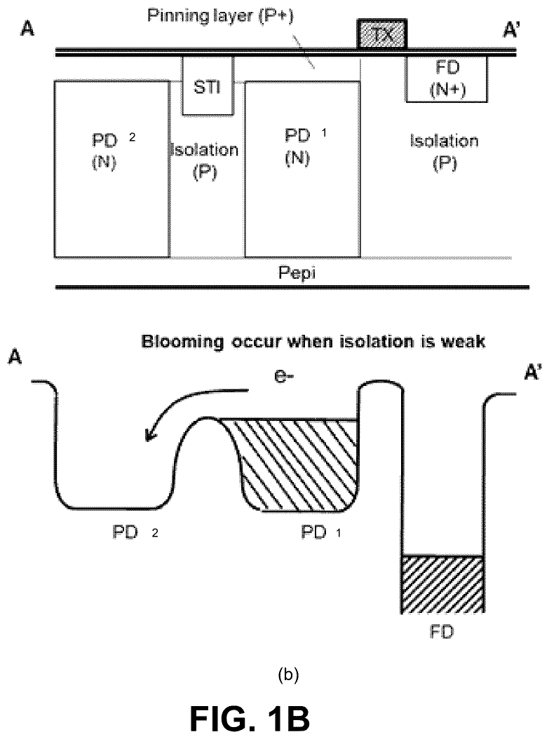

FIGS. 1A and 1B show the example of blooming. FIG. 1A shows a top view of a pixel layout, and FIG. 1B shows a cross-section view of FIG. 1A along cutline A-A′ along with a corresponding potential diagram.

FIGS. 1A and 1B respectively illustrate a first photodiode PD1, pixel transistors (e.g., reset transistor, source follower transistor, row select transistor) arranged within a pixel region of a first pixel. The first photodiode PD1 is coupled to a corresponding floating diffusion FD via a respective transfer gate TX (first transfer gate). Photo-generated electrons in the first photodiode PD1 are transferred to a floating diffusion FD via the transfer gate TX in response to a first transfer signal. For example, first transfer signal can turn transfer gate TX “ON” to provide a conduction or channel path between the first photodiode PD and the floating diffusion FD. Transfer gate TX included in the first pixel has a planar gate and one or more vertical gate VTG extending from the planar gate to facilitate charge transfer providing lag improvement. In the illustrated example, the transfer gate TX included in the first pixel employs a dual vertical transfer gate structure. Blooming is shown in the potential diagram of cross-section in AA′. This leakage is unexpected signal for neighbor pixel, so image quality will be degraded. The first photodiode PD1 is electrically isolated from a second photodiode PD2 included in an adjacent pixel (second pixel) by a shallow trench structure STI and a deep trench isolation structure (DTI). The first photodiode PD1 may further be isolated from the second photodiode PD2 by a junction isolation formed of impurity region doped with dopant having opposite conductive type as the first and second photodiodes PD1, PD2.

As can be seen from FIGS. 1A and 1B, when an isolation between first pixel and second pixel is weak, charges photogenerated from one photodiode region may leak to an adjacent photodiode region inducing electrical crosstalk. For example, charges may leak from first photodiode PD1 of first pixel to a second photodiode PD2 of a second pixel disposed adjacent to first pixel as illustrated by a dashline arrow in FIG. 1B.

Shallow trench isolation structure STI in the illustrated example is used for the purpose of isolation between active nodes, but a shallow trench isolation structure STI takes a certain area size, for example area reserved may need trench dimension with additional process margin) on a substrate, as such other active area (e.g., photodiode area) tends to be smaller. That is, employing isolation scheme using STI could place unnecessary size constraint on the photodiode area of individual pixel. In addition, there could be an etching damage (e.g., plasma etching) induced during trench formation of shallow trench isolation structure STI leasing to dark current and white pixel issue degrading image quality. However, when shallow trench isolation structure between first pixel and second pixel is replaced by junction isolation in considering of increasing pixel area and mitigate dark current issue associated with shallow trench isolation structure, isolation between first pixel and second pixel may become weaker due to weak potential barrier without shallow trench isolation structure STI.

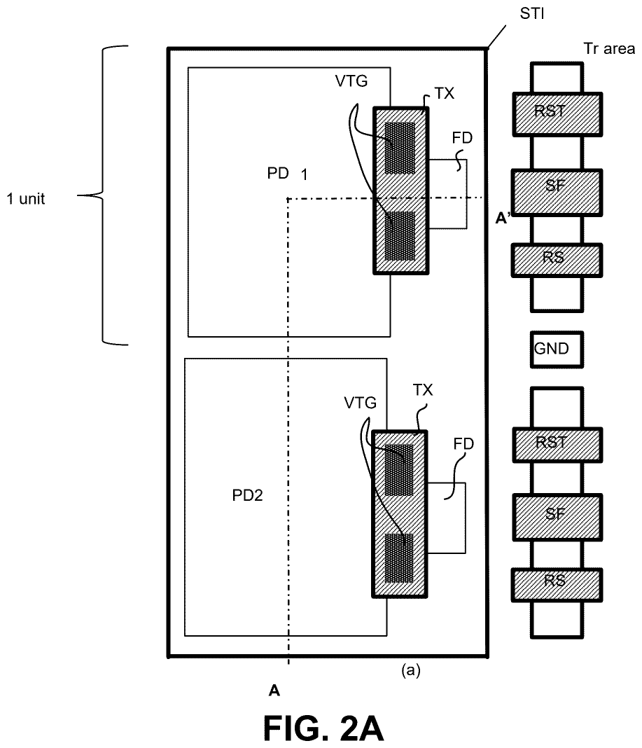

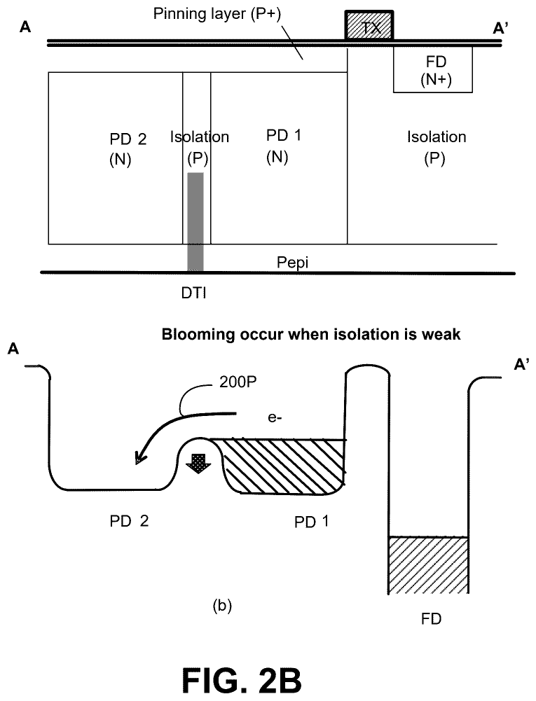

FIGS. 2A and 2B show the example of blooming. FIG. 2A shows a top view of a pixel layout, and FIG. 2 (b) shows a cross-section view of FIG. 1A along cutline A-A′ along with a corresponding potential diagram. For example, as shown in FIG. 2B, shallow trench isolation structure STI is not used between first photodiode PD1 of a first pixel and second photodiode PD2 of a second pixel adjacent to first pixel. Instead, a junction isolation type structure formed of one or more impurity doping may be formed or otherwise disposed between first photodiode PD1 of first pixel and second photodiode PD2 of second pixel. The leakage toward neighbor photodiode (e.g., to second photodiode PD2 of second pixel as illustrated by path 200P) is likely to be more serious causing electrical crosstalk because junction isolation type structure may provide weak potential barrier compare to shallow trench isolation structure STI.

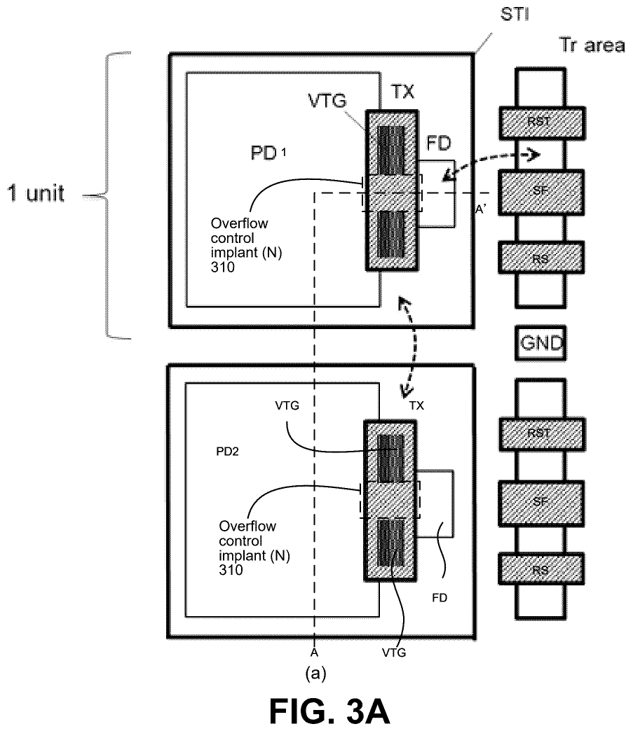

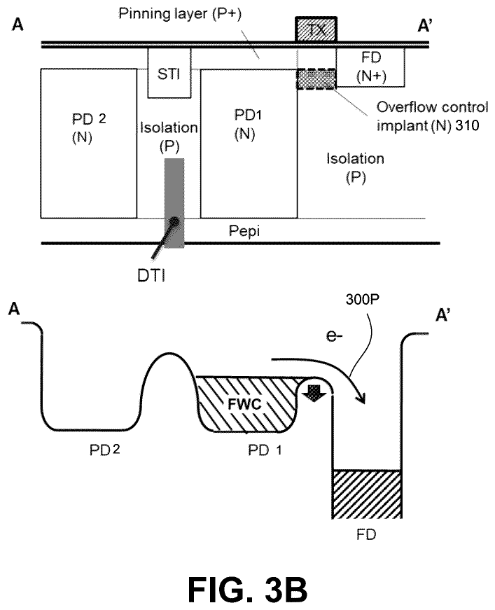

FIGS. 3A and 3B illustrate an example of pixels structure with a blooming path in accordance to teaching of present teaching. FIG. 3A shows a top view of a pixel layout, and FIG. 3B shows a cross-section view of FIG. 3A along cutline A-A′ along with a corresponding potential diagram. In this example, an implanted doped region forming an overflow control implant 310 is formed (via ion implantation) or otherwise disposed between first photodiode PD1 and the coupled floating diffusion FD. The overflow control implant 310 has a conductive type same as the first photodiode PD1 and the floating diffusion FD. The overflow control implant is implanted to provide an overflow path from the first photodiode PD1 to the floating diffusion FD of the first pixel as illustrated by path 300P. The overflow control implant enables a potential barrier between the first photodiode PD1 and the floating diffusion of the first pixel to be lowered than a potential barrier between the first photodiode PD1 and the second photodiode PD2 of the adjacent second pixel such that when the first photodiode PD1 saturates (e.g., amount of accumulated photogenerated charges exceeding a full well capacity of the first photodiode PD1), for example in response to a strong or bright light, blooming will not occur as excess photogenerated charges overflows to the coupled floating diffusion FD. However, lowering potential barrier could also lower the full well capacity or sensitivity of first photodiode PD1.

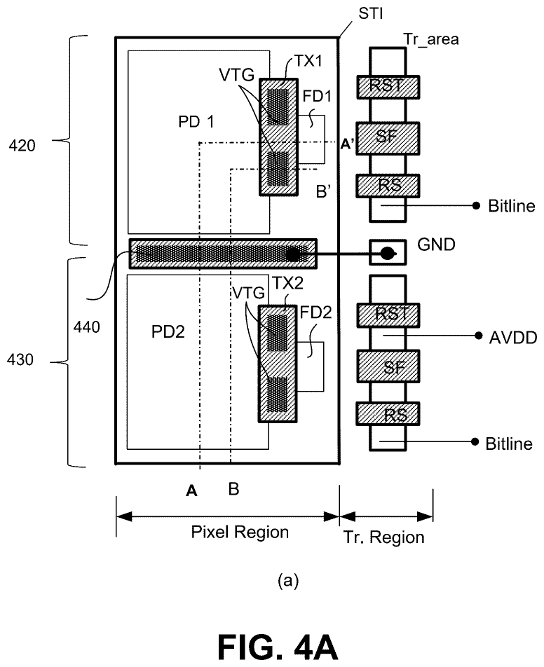

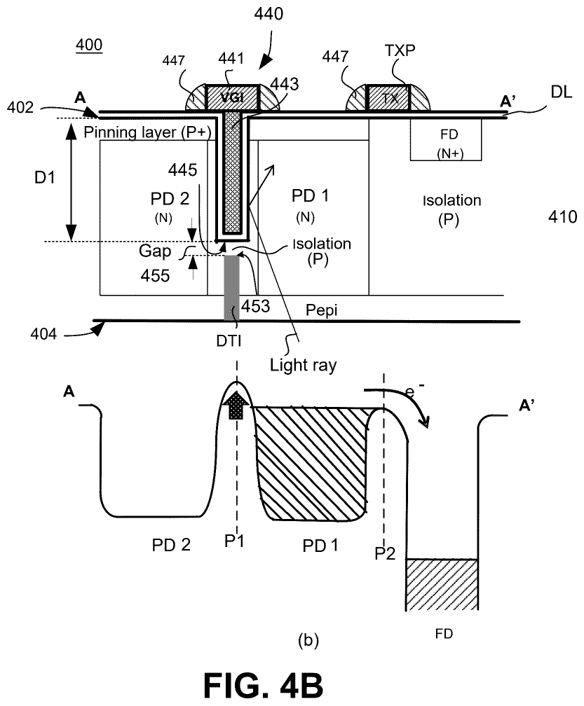

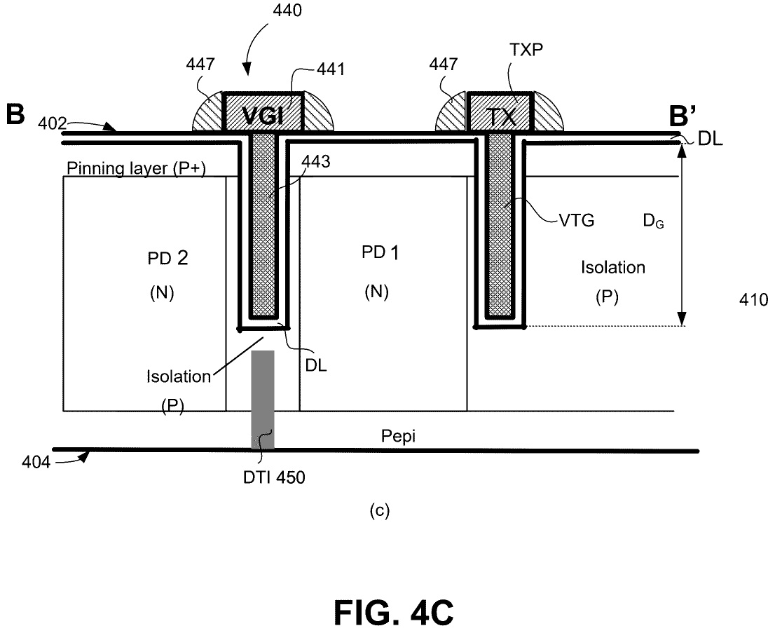

FIGS. 4A-4C illustrate an improved example pixel structure having vertical gate electrode arranged between adjacent photodiodes in accordance to the teaching of present disclosure.

FIG. 4A illustrates a top view of a pixel layout for pixel array 400 including a pixel region and a transistor region, wherein a vertical gate electrode disposed between a first photodiode PD1 of a first pixel 420 and a second photodiode PD2 of a second pixel 430, in accordance with the teachings of the present disclosure. Pixel array 400 is disposed or otherwise formed on a semiconductor layer 410 (e.g., silicon, a silicon germanium alloy, germanium, a silicon car-bide alloy, an indium gallium arsenide alloy, any other alloys formed of III-V compounds, other semiconductor materials or alloys, combinations thereof, a substrate thereof, a doped substrate thereof, a bulk substrate thereof, or a wafer thereof) having a front side surface 402 and a backside surface 404 opposite to the front side surface. In the illustrated embodiment, first photodiode PD1 of the first pixel 420, the second photodiode PD2 of the second pixel 430, transfer gates TX1, TX2, and floating diffusions FD1, FD2 are formed or otherwise disposed in pixel region on the semiconductor layer 410 proximate to front side surface 402. Pixel transistors such as reset transistor, source follower, row select transistor are formed or otherwise disposed in transistor region on the semiconductor layer 410 proximate to front side surface 402. FIG. 4B illustrates a cross-sectional view along line A-A′ and corresponding potential diagram, in accordance with the teachings of the present disclosure. FIG. 4C illustrates a cross-sectional view along line B-B′, in accordance with the teachings of the present disclosure.

The first photodiode PD1 is coupled to a first floating diffusion FD1 included in the first pixel through a corresponding first transfer gate TX1 included in the first pixel 420 for transferring photogenerated charges to first floating diffusion. The second photodiode PD2 is coupled to another floating diffusion (second floating diffusion) FD2 through a corresponding second transfer gate TX2 included in the second pixel 430 for transferring photogenerated charges to second floating diffusion. Alternatively, the first transfer gate TX1 selectively couple the first photodiode PD1 to first floating diffusion FD1 of first pixel 420. The second transfer gate TX2 selectively couple the second photodiode PD2 to second floating diffusion FD2 of second pixel 430. Each of the first and second transfer gates TX1, TX2 includes a planar gate TXP disposed proximate to the front side surface 402 (first side surface) of the semiconductor layer 410 and one or more vertical transfer gates VTG (as illustrated in FIG. 4C) extending from the corresponding planar gate TXP a gate depth DG into the semiconductor layer 410. Pixel array 400 further includes one or more vertical gate isolation structures VGI 440 is disposed between the first photodiode PD1 and the second photodiode PD2. Each of the vertical gate isolation structure VGI 440 includes a planar gate portion 441 and a vertical gate electrode 443. The vertical gate electrode 443 extends from the planar gate portion 441 a depth D1 into the semiconductor layer 410. The gate depth DG that vertical transfer gate VTG of each transfer gate in various examples extended from the corresponding planar gate and the depth D1 that each of vertical gate isolation structures VGI 440 extends may be same i.e., the vertical gate isolation structure VGI 440 and vertical transfer gate VTG may extend to a common depth in semiconductor layer 410. In same or different embodiments, the planar gate portion 441 of each vertical gate isolation structure VGI 440 and the planar gate TXP of each of transfer gate TX1, TX2 disposed on front side surface 402 may be surrounded by spacer material 447 as insulator providing process protection (such as protect gate structure during ion implantation for forming source and drain regions. Spacer material 447 may be formed of silicon nitride, silicon oxide or a combination thereof. Spacer material 447 may be of a single layer or a multilayer structure. In same or different embodiments, the planar gate portion 441 of each vertical gate isolation structure VGI 440 may not have spacer material surrounding respective planar gate portion 441. In same or different embodiments, the planar gate portion 441 of each vertical gate isolation structure VGI 440 and the planar gate TXP of each of transfer gate TX1, TX2 disposed on front side surface 402 are encapsulated by an inter-layer dielectric (not illustrated)

The vertical gate electrode 443 of the vertical gate isolation structure VGI may comprise a conductive material such as polysilicon or metallic material e.g., tungsten or aluminum. The planar gate 441 and the vertical gate electrode 443 of the vertical gate isolation structure VGI are separated from the semiconductor layer 410 by a dielectric layer DL. The dielectric layer DL may be disposed proximate to the front side surface 402 of the semiconductor layer 410 between planar gate of transfer gates TX1, TX2 and front side surface 402 of the semiconductor layer 410, and between planar gate portion 441 of vertical gate isolation structure VGI and the front side surface 402 of the semiconductor layer. The dielectric layer DL may in some embodiment formed of oxide-based material.

In some embodiments, the vertical gate isolations structure VGI and the transfer gates TX1, TX2 may have same material composition, for example formed of polysilicon. In same or different embodiments, the vertical gate electrode VG of the vertical gate isolation structure VGI and the vertical transfer gate VTG may have identical structure characteristic including same structural profile, common gate depth in the semiconductor layer, same gate widths. In same or different embodiments, the vertical gate isolations structure VGI and the transfer gates TX1, TX2 may be formed in the same process.

The vertical gate isolations structure VGI 440 may be vertically aligned with a backside deep trench isolation structure 450, wherein the backside deep trench isolation structure 450 that is extended from a backside surface 404 (second side) of the semiconductor layer 410 a depth into semiconductor layer. The backside deep trench isolation structure 450 and vertical gate isolations structure VGI 440 may comprise of different material. For example, the backside deep trench isolation structure 450 may be oxide-based trench isolation structure.

In some embodiments, there exist a gap 455 in the semiconductor layer 410 between the vertical gate isolations structure VGI 440 and the backside deep trench isolation structure 450. That is, a bottom end 453 of the backside deep trench isolation structure 450 and a bottom end 445 of the vertical gate electrode 443 of the vertical gate isolation structure VGI 440 are separated by a semiconductor material of the semiconductor layer 410. In some embodiments, there may not be a gap 455 between the bottom end 453 of the backside deep trench isolation structure 450 and the bottom end 445 of the vertical gate electrode 443 of the vertical gate isolation structure VGI. In such example, the bottom end 445 of the backside deep trench isolation structure 450 may be in a direct contact with the bottom end 445 of the vertical gate electrode 443 of the vertical gate isolation structure VGI 440.

In the illustrated embodiment, the vertical gate isolation structure VGI 440 and the backside deep trench isolation structure 450 are disposed in p-type doped region in the semiconductor layer 410. The vertical gate isolation structure VGI 440 and the backside deep trench isolation structure 450 may be surrounded by the p-type isolation region.

The vertical gate isolation structure VGI 440 provides a physical isolation between first photodiode PD1 and the second photodiode PD2. The vertical gate isolation structure VGI 440 is further configured to couple to receive a ground reference voltage GND. As such, blooming can be prevented because of higher potential barrier (e.g., position P1 in potential diagram in FIG. B) between first photodiode PD1 and second photodiode PD2. The potential barrier level at position P1 is greater potential barrier level at position P2. Furthermore, crosstalk against neighboring photodiodes by incident light (e.g., illustrated light ray) with certain angle can also be suppressed by reflection and/or refraction. In this embodiment, overflow control implant as shown in FIG. 3 is not necessary, and number of photolithography masks in silicon process can be reduced. Further, shallow trench isolation can be removed, enabling further pixel size shrinkage and improving dark current performance.

In some embodiments, the vertical gate isolation structure VGI 440 may be configured to couple to a negative bias voltage, form a hole accumulation region around the vertical gate electrode 443 in the semiconductor layer 410 to passivate surface region of the vertical gate electrode 443.

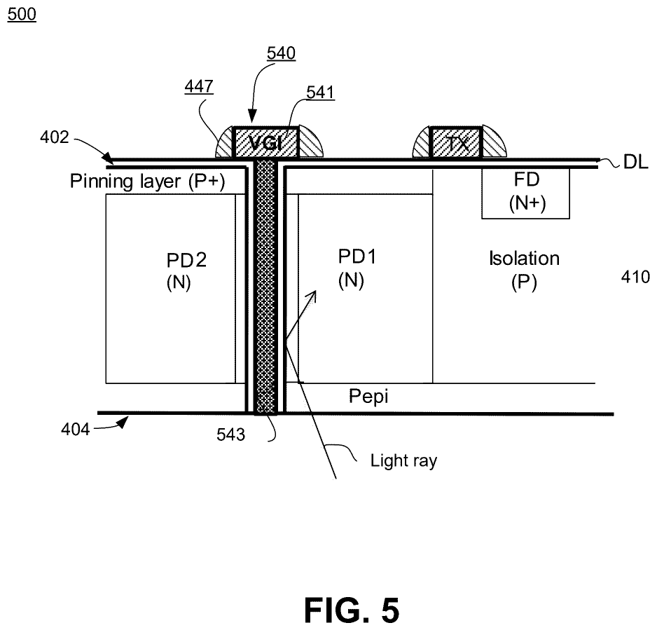

In some embodiments, the vertical gate electrode 443 of vertical gate isolation structure VGI 450 may extend throughout the semiconductor layer 410, for example as shown in FIG. 5. It is noted that pixel array 500 provides another embodiment according to the present disclosure, and that similarly named and numbered elements referenced below are coupled and function similar to as described above. Indeed, it is appreciated that pixel array 500 of FIG. 5 shares many similarities with cross-sectional view of pixel array 400 depicted FIG. 4B and FIG. 4C. As such, it is appreciated that the differences between pixel array 500 and pixel array 400 will be described in detail herein for the sake of brevity and in order to avoid obscuring the teachings of the present invention. In FIG. 5, pixel array 500 include a first pixel 420 and second pixel 430, wherein pixel array 500 includes a vertical gate isolation structure VGI 540, which is an example of vertical gate isolation structure VGI 440 but with a vertical thickness of vertical gate electrode 543 of vertical gate isolation structure VGI 540 being the same as a vertical thickness of the semiconductor layer 410. That is vertical gate electrode 543 of vertical gate isolation structure VGI 540 is a through semiconductor layer structure

The vertical gate isolation structure VGI 540 provides a complete separation (e.g., from front side surface 420 to the backside surface 404 of the semiconductor layer 410) between first photodiode PD1 of first pixel 420 and second photodiode PD2 of second pixel 430. In addition to pixel performance improvement as explained in the previous example, this modified structure in FIG. 5 can improve crosstalk more strongly for wider wavelength because of complete separation in the depthwise direction. FIG. 5 can further suppress crosstalk mainly for longer wavelength relatively as vertical gate isolation structure VGI 540 of FIG. 5 exists at a depth away from the backside surface (of an illuminated side) where the light incident.

The example of FIG. 5, provides benefits in that 1) additional process steps regarding from backside may not be necessary, and 2) a front side metal routing configure to bias (for example, ground or negative voltage) vertical gate isolation structure VGI 540 is possible. That is, since the vertical gate electrode 543 is disposed up to the irradiation surface, the ground wiring can be routed on the irradiation side and connected to the vertical gate electrode 543.

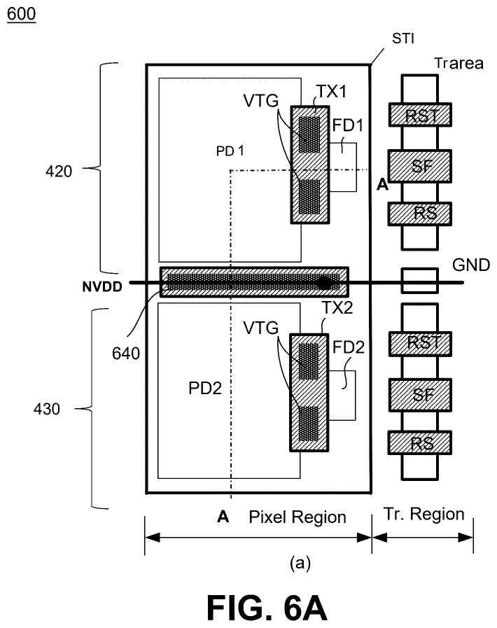

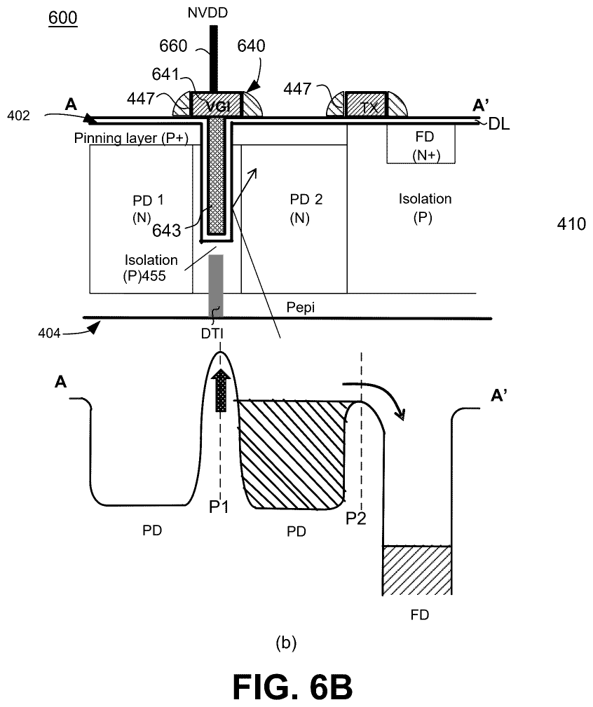

FIGS. 6A and 6B show another example pixel array 600 having vertical gate isolation structure 640 coupled to receive a bias voltage via a metal interconnect 660, in accordance to the teaching of present disclosure, and that similarly named and numbered elements referenced below are coupled and function similar to as described above. For example, vertical gate isolations structure may be configured to connect a dedicated horizontal metal line to receive negative voltage (labeled NVDD), that is included in metal layers. Because negative voltage is applied to vertical gate isolation structure 640, many holes are accumulated in the semiconductor layer 410 forming hole accumulation region at or proximate to the front side surface 402 of the semiconductor layer 410 around vertical gate isolations structure 660 passivating sidewall surface, for example around planar gate portion 641 and vertical gate electrode 643. Therefore, potential barrier around vertical gate isolations structure VGI 640 at position P1 (shown in FIG. 6B) becomes higher than previous example. Blooming as such can be further suppressed, and accordingly dark current or white pixels from the surface of vertical gate isolation structure VGI 640 also can be suppressed by higher hole concentration accumulated at the surface of vertical gate VG of vertical gate isolation structure VGI 640.

In some embodiments, the vertical gate isolation structure VGI 640 can be disposed to isolate and separate adjacent photodiodes and between photodiodes PD1, PD2 in pixel region and pixel transistors such as reset transistor, source follower, row select transistor disposed in transistor region.

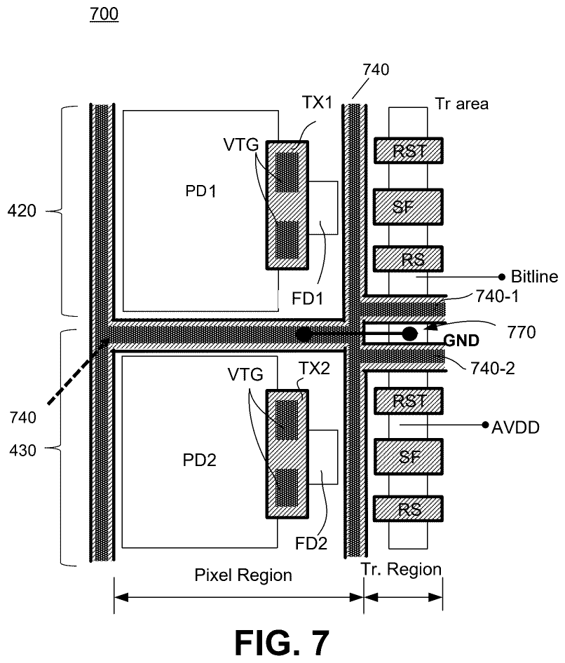

FIG. 7 provides further another example configuration of pixel array having vertical gate isolation structure according to present disclosure and that similarly named and numbered elements referenced below are coupled and function similar to as described above. Indeed, it is appreciated that pixel array 700 of FIG. 7 shares many similarities with cross-sectional view of pixel array 400 depicted FIGS. 4B and 4C. As such, it is appreciated that the structural differences between pixel array 600 and pixel array 400, e.g., electrical connection to the vertical gate isolation structure VGI will be described in detail herein for the sake of brevity and in order to avoid obscuring the teachings of the present invention. As illustrated in FIG. 7, pixel array 700 that includes a vertical gate isolation structure VGI 740 surrounding individual photodidoes PD1, PD2. The vertical gate isolation structure VGI 740 can be disposed surrounding each of individual photodiodes PD1, PD2, providing isolation therebetween. The vertical gate isolation structure VGI 740 may further be disposed separating pixel region and transistor region providing isolation between individual photodiodes PD1, PD2 and pixel transistors e.g., row select transistor, source follower transistor, reset transistor. The vertical gate isolation structure VGI 740 may be arranged in a grid form defining pixel regions and transistor regions. The vertical gate isolation structure VGI 740 may further be disposed between transistor regions (Tr. region) e.g., between row select transistor and ground contact region 770. The vertical gate isolation structure VGI 740 separates source/drain of transistors, source/drain of transistors and ground contact region 770. For example, the vertical gate isolation structure VGI 740 include a first vertical gate isolation segment 740-1 disposed between source of row select transistor and ground contact region 770, wherein the source of row select transistor is coupled to a bitline for read out charge associated with first pixel 420. The vertical gate isolation structure VGI 740 further include a second vertical gate isolation segment 740-2 disposed between source of reset transistor and ground contact region 770. In various of example, ground contact region 770 may be a region in the semiconductor layer 410 heavily doped with an impurity having conductive type opposite to photodiode doped region of photodiode PD1, PD2 or floating diffusion FD. In one embodiment, ground contact region 770 may be of P-type such as boron-doped region. In one embodiment, ground contact region 770 is coupled to receive a ground reference voltage GND. In one embodiment, ground contact region 770 and vertical gate isolation structure VGI 740 are coupled receive the ground reference voltage GND.

The arrangement and size of vertical gate isolation structure VGI 740 may be configured taking pixel performance improvement like blooming, full well capacity, and electrical/optical crosstalk into consideration. Further, the vertical gate isolation structure VGI 740 can be manufactured simultaneously with the transfer gates such as transfer gates TX1, TX2. By sharing mask for vertical gate isolation structure VGI 740 and vertical transfer gates VTG the number of masks used in pixel fabrication process, STI and overflow control implantation stages can be reduced, lower overall sensor production cost.

In other embodiments, pixel transistors and photodiodes may be arranged to be formed on different wafers to maximize pixel area. Image sensor having such structure may be referred as two-layer pixel structure. The two-layer pixel structure may include a pixel wafer and a pixel transistor wafer, wherein the pixel wafer layer is stacked with the pixel transistor wafer layer.

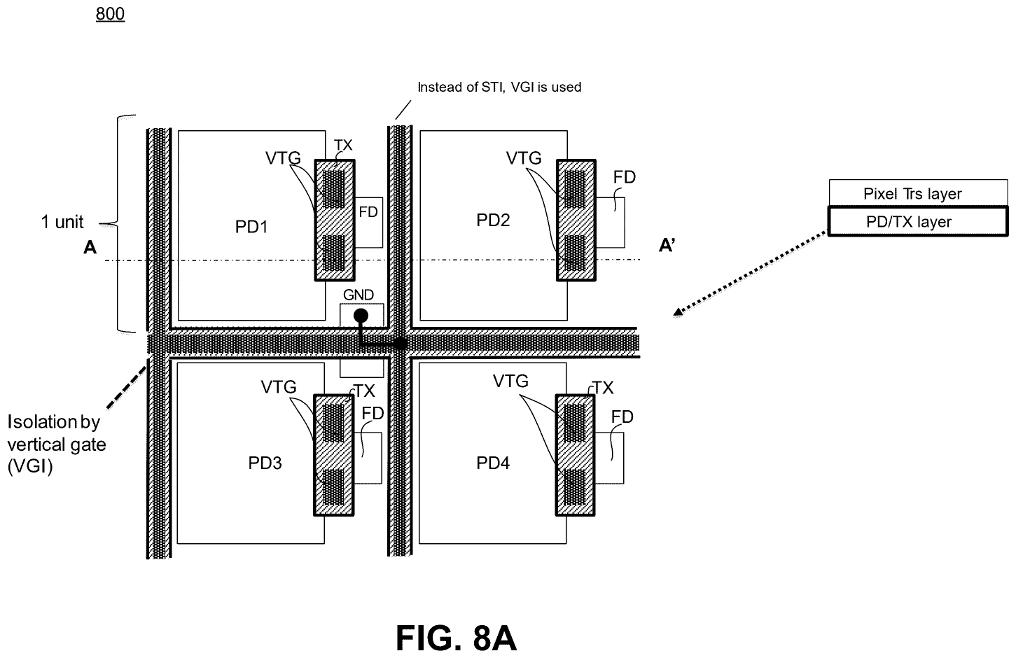

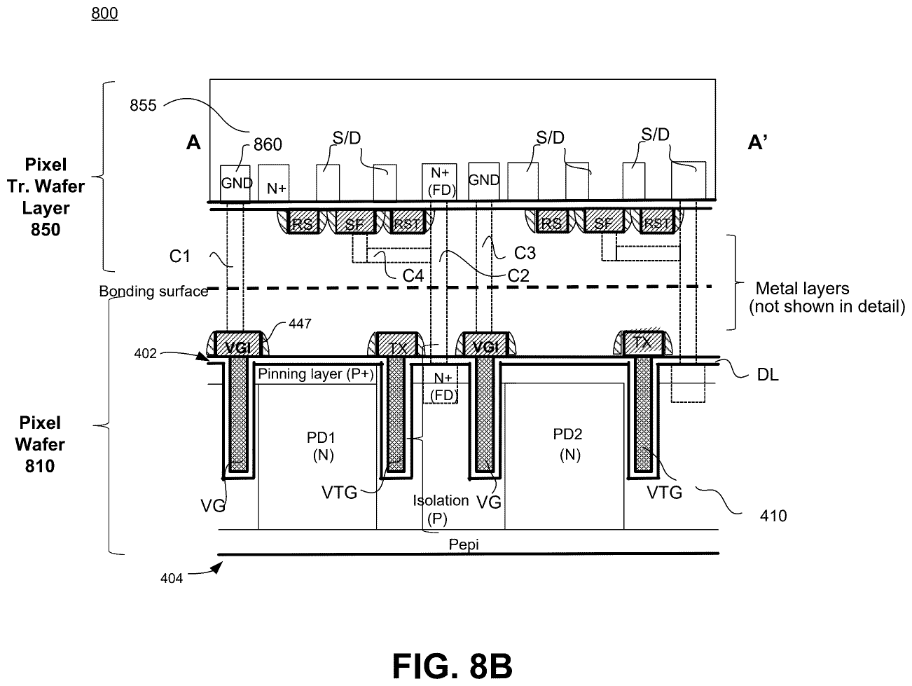

FIG. 8A and FIG. 8B provides an example implementation of pixel array 800 formed of 2-layer pixel structure image sensor, in accordance to the teaching of present disclosure. FIG. 8A illustrates a top view of a pixel layout for the pixel wafer layer (PD/TX layer) 810 included in two-layer pixel structure. FIG. 8B illustrates a line A-A of FIG. 8A. In FIG. 8B, the contacts of the reset transistor RST-Tr, the row selection transistor RS-Tr, and the transfer gate TX are not shown. Pixel transistors such as source follower transistor SF-Tr, reset transistor RST-Tr, and row-select transistor RS-Tr arranged to be disposed or otherwise formed on the pixel transistor wafer layer (or second wafer) 850, such that larger size of photodiode can be realized maximizing full well capacity of individual photodiode because the pixel wafer layer (or first layer) 810 comprising only plurality of photodiodes (e.g., photodiode) PD1, PD2, transfer gates TX, and floating diffusions FD. Pixel transistors such as source follower transistor SF-Tr, reset transistor RST-Tr, and row-select transistor RS-Tr arranged may be formed in semiconductor layer 855 of pixel transistor wafer layer 850. The pixel transistor wafer layer 850 may be stacked on the pixel wafer layer 810 and bonded for example via front to front (or face to face) bonding scheme and employ vertical interconnection structure e.g., through silicon vias for component connection between the pixel wafer layer 810 and pixel transistor wafer layer 850. The semiconductor layer 410 of the pixel wafer layer 810 and the semiconductor layer 855 of pixel transistor wafer layer 850 can be of any thickness that allows the desired property or functionality of the semiconductor device, and thus any such thickness of semiconductor material is considered to be within the present scope. In some embodiments, the semiconductor layer 410 of the pixel wafer layer 810 and the semiconductor layer 855 of pixel transistor wafer layer 850 may have different thickness. For example, a depthwise thickness of the semiconductor layer 855 of pixel transistor wafer layer 850 may be thinner than the semiconductor layer 410 of the pixel wafer layer 810. Floating diffusions FD of the pixel wafer layer 810 is connected to source follower gate of source follower SF-Tr, for example through connection structure C4 and source of reset transistor RST-Tr on pixel transistor wafer layer 850 for readout and reset operation through corresponding metal/via interconnection structure e.g., connection structures C2. On the pixel wafer layer 810, the vertical gate isolation structure VGI is disposed to provide separation and isolation between adjacent photodiodes (such as between photodiode PD1 and photodiode PD3) and between photodiodes and corresponding floating diffusion FD coupled, achieving better pixel performance.

The vertical gate isolation structure VGI on the pixel wafer layer 810 can be connected to a ground contact region to received ground reference through a corresponding metal via connection structure e.g., connection structure C1, C3. The ground contact region may be a semiconductor region doped with an impurity having conductivity type as the semiconductor layer and opposite to photodiode doped region of photodiodes and floating diffusions, such as p-type doped. Each of connection structure C1, C3 may extend through the pixel transistor wafer layer, the bonding interface to be in connection with corresponding vertical gate isolation structure VGI providing biasing voltage to the vertical gate isolation structure VGI. In various examples, the ground contact region 860 on the pixel transistor wafer layer 850 may be vertically aligned with vertical gate isolation structure VGI or corresponding portion of vertical gate isolation structure VGI on pixel wafer layer. In various examples, the ground contact region 860 on the pixel transistor wafer layer 850 may be disposed between source of row select transistors RS-Tr and source of reset transistor RST-Tr. The ground contact region 860 on the pixel transistor wafer layer 850 may be a region doped with impurity having conductive type opposite to that of photodiode doped region and floating diffusion FD. The ground contact region 860 on the pixel transistor wafer layer 850 may be a region doped with impurity having conductive type that is same as that of the semiconductor layer 855 of pixel transistor wafer layer 850. Source and drain regions 540 for pixel transistors and ground contact region 860 may be formed monolithically on a common semiconductor layer 855. Source of row select transistors RS-Tr is coupled to a respective bitline for outputting image signal for the corresponding photodiode.

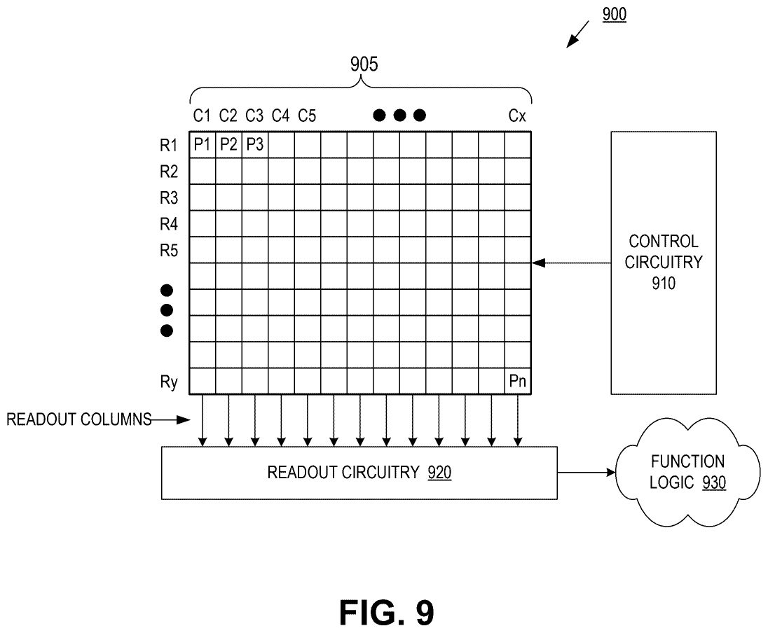

FIG. 9 illustrates a block diagram of an imaging system 900, in accordance with an embodiment of the present disclosure.

Imaging system 900 includes pixel array 905, control circuitry 910, readout circuitry 920, and function logic 930. In one embodiment, pixel array 905 is a two-dimensional (2D) array of photodiodes, or image sensor pixels (e.g., pixels P1, P2 . . . , Pn). Each individual photodiodes, or image sensor pixels are separated and isolated by vertical gate isolation structure illustrated in FIG. 4, 5, 6, 7, or 8. As illustrated, photodiodes are arranged into rows (e.g., rows R1 to Ry) and columns (e.g., column C1 to Cx) to acquire image data of a person, place, object, etc., which can then be used to render an image or video of the person, place, object, etc. However, photodiodes do not have to be arranged into rows and columns and may take other configurations. Each of image sensor pixels may include a vertical gate structure for improving charge transfer efficiency.

In one embodiment, after each image sensor photodiode/pixel in pixel array 905 has acquired its image data or image charge, the image data is readout by readout circuitry 920 and then transferred to function logic 930. In various examples, readout circuitry 920 may include amplification circuitry, analog-to-digital (ADC) conversion circuitry, or otherwise. Function logic 930 may simply store the image data or even manipulate the image data by applying post image effects (e.g., autofocus, crop, rotate, remove red eye, adjust brightness, adjust contrast, or otherwise). In the same or another embodiment, readout circuitry 920 may readout a row of image data at a time along readout column lines (illustrated) or may readout the image data using a variety of other techniques (not illustrated), such as a serial readout or a full parallel readout of all pixels simultaneously. In one embodiment, control circuitry 930 is coupled to pixel array 905 to control operation of the plurality of image sensor pixels in pixel array 905. For example, control circuitry 910 may generate a shutter signal for controlling image acquisition. In some embodiments, control circuitry 910 may be configured to generate drive signals e.g., transfer signals, reset signals, and row-select signals for controlling the operation of pixel circuitries associated with pixels in image sensor pixel array 905.

It is appreciated that imaging system 900 may be included in a digital camera, cell phone, laptop computer, automobile, or the like. Additionally, imaging system 100 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 300, extract image data from imaging system 100, or manipulate image data supplied by imaging system 900.

It is further appreciated that while the block diagram illustrated in FIG. 9 shows pixel array 905, readout circuitry 920, function logic 930, and control circuitry 910 as distinct and separate elements from the pixel array, this is not necessarily the case as such features may be combined or otherwise incorporated with the pixel array directly (e.g., within and/or between individual pixels, in the form of stacked substrates, or otherwise). For example, the readout circuitry 920 may include one or more transistors (e.g., associated with 3T, 4T, 5T, or other pixel architectures for reading out image charge from individual pixels), elements of which may be disposed between segments of individual photodiodes in accordance with embodiments of the present disclosure. Furthermore, the image sensor 900 may include features not explicitly illustrated or discussed but known by one of ordinary skill in the art such as color filters, microlenses, a metal grids, and the like. Additionally, it is appreciated that image sensor 100 is fabricable by conventional CMOS manufacturing techniques known by one of ordinary skill in the art, which may include, but is not limited to, photolithography, chemical vapor deposition, physical vapor deposition, ion implantation or diffusion, thermal oxidation, reactive ion etching, wet chemical etching, and view of the foregoing disclosure.

In one example, imaging system 900 is implemented on a single semiconductor wafer. In another example, imaging system 900 is on stacked semiconductor wafers. For example, pixel array 905 with vertical gate isolation structure VGI is implemented on a pixel wafer or a sensor wafer, and readout circuit 920, control circuit 910 and function logic 930 are implemented on an application specific integrated circuit (ASIC) wafer, where the pixel wafer and the ASIC wafer are stacked and interconnected by bonding (hybrid bonding, oxide bonding, or the like) or one or more through substrate vias (TSVs). For another example, pixel array 905 with vertical gate isolation structure VGI and control circuit 930 are implemented on a pixel wafer, and array of capacitors, readout circuit 920, and function logic 930 are implemented on an ASIC wafer, where the pixel wafer and the ASIC wafer are stacked and interconnected by bonding (hybrid bonding, oxide bonding, or the like) or one or more through substrate vias (TSVs). In another example, portions of each image sensor pixel in the pixel array 905, including for example the photodiode, the transfer transistors, floating diffusion or part of floating diffusion and vertical gate isolation structure VGI or grid of vertical gate isolation structure VGI are included in a first wafer (pixel wafer), while at least one of source follower transistors, reset transistors, row select transistors, and other pixel transistors such as overflow transistor, dual conversion gain transistors are included in a second wafer (pixel transistor wafer), and the control circuitry 930 and ASIC circuitry are included in a third wafer that is stacked with the first and second wafers, etc. vertical gate isolation structure VGI may through connection structure coupled to corresponding ground contact on the second wafer in a vertical stacking manner or a corresponding voltage source providing negative bias voltage.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An image sensor, comprising:
a semiconductor layer having a first side and a second side opposite to the first side, the semiconductor layer including a first photodiode and a second photodiode adjacent to the first photodiode;
a floating diffusion disposed within the semiconductor layer proximate to the first side; and
a transfer gate disposed on the semiconductor layer to couple the first photodiode to the floating diffusion, the transfer gate comprising a vertical transfer gate extending a gate depth from the first side of the semiconductor layer into the semiconductor layer; and
a vertical gate structure disposed on the semiconductor layer between the first photodiode and the second photodiode, the vertical gate structure including a planar portion disposed proximate to the first side and a vertical gate portion extending a depth from the planar portion into the semiconductor layer;
wherein the gate depth is the same as the depth that the vertical gate portion of the vertical gate structure extends.

2. The image sensor according to claim 1, wherein the transfer gate and the vertical gate structure are formed of the same composition.

3. The image sensor according to claim 2, wherein the transfer gate and the vertical gate structure comprise polysilicon.

4. The image sensor according to claim 1, further comprising a second vertical gate structure disposed to separate the first photodiode from a transistor region containing at least one of a row select transistor, a reset transistor, or a source follower transistor.

5. The image sensor according to claim 4, further comprising a third vertical gate structure disposed to separate a transistor from a ground contact.

6. The image sensor according to claim 5, wherein the vertical gate structure and the second vertical gate structure are interconnected so as to surround the first photodiode.

7. The image sensor according to claim 1, wherein the vertical gate structure is coupled to receive a ground reference voltage or a negative bias voltage.

8. The image sensor according to claim 1, wherein the depth of the vertical gate structure is same as the depth of the semiconductor layer.

9. The image sensor according to claim 1, wherein the semiconductor layer is a first wafer layer including thereon the vertical gate structure and the first photodiode, and at least one of a row select transistor, a reset transistor, or a source follower transistor is disposed on a second wafer layer vertically stacked on the first wafer layer.

10. The image sensor according to claim 9, wherein a ground contact is vertically aligned with the vertical gate structure.

11. The image sensor according to claim 10, wherein the ground contact is coupled to the vertical gate structure through a vertical contact structure.

12. The image sensor according to claim 1, further comprising a backside deep trench isolation structure disposed on the second side of the semiconductor layer, wherein the backside deep trench isolation structure is vertically aligned with the vertical gate structure.

13. The image sensor according to claim 12, wherein a vertical gap is located between the vertical gate structure and the backside deep trench isolation structure.

14. The image sensor according to claim 1, wherein the vertical gate structure is separated from the semiconductor layer by a dielectric layer.

15. An image sensor, comprising:
a first wafer comprising;
a first semiconductor layer having a first side and a second side opposite to the second side;
a photodiode having a photodiode doped region, the photodiode disposed within the first semiconductor layer proximate to the first side of the first semiconductor layer;
a floating diffusion disposed within the first semiconductor layer proximate to the first side;
a transfer gate disposed on the semiconductor layer to couple the first photodiode to the floating diffusion, the transfer gate comprising a vertical transfer gate extending a gate depth from the first side of the semiconductor layer into the first semiconductor layer; and
a vertical gate structure disposed on the first semiconductor layer between the photodiode and a photodiode doped region of a second photodiode adjacent to the first photodiode, the vertical gate structure including a planar portion disposed proximate to the first side and a vertical gate portion extending a depth from the planar portion into the first semiconductor layer; and
a second wafer stacked on the first wafer comprising;
a second semiconductor layer disposed on the first semiconductor layer; and
a doped region having an impurity polarity identical to that of the second semiconductor layer, the doped region coupled to receive a ground voltage;
wherein the doped region is coupled to the vertical gate structure.

16. The image sensor according to claim 15, wherein the doped region is vertically aligned with the vertical gate structure.

17. The image sensor according to claim 16, further comprising a vertical contact structure coupled to the doped region and the vertical gate structure.

18. The image sensor according to claim 15, wherein the second wafer further comprises at least one of a row select transistor, a reset transistor, or a source follower transistor disposed on a second semiconductor layer.

19. The image sensor according to claim 15, wherein the gate depth is equal to the depth that the vertical gate portion of the vertical gate structure extends.

20. The image sensor according to claim 15, further comprising a second vertical gate structure that is disposed between the floating diffusion and a photodiode doped region of a third photodiode adjacent to the second photodiode.
